(19) United States
(12) Patent Application Publication
(10) Pub. No.: US 2007/0199679 A1
(43) Pub. Date: Aug. 30, 2007

(54) Chip Heat Dissipation System and Manufacturing Method and Structure of Heat Dissipation Device Thereof

(76) Inventors: Ming-Hang Hwang, Taipei City (TW); Yu-Chiang Cheng, Taipei City (TW); Chao-Yi Chen, Taipei City (TW); Ping-Feng Lee, Taipei County (TW); Hsin-Lung Kuo, Taipei City (TW); Bin-Wei Lee, Taipei City (TW); Wei-Chung Hsiao, Taipei City (TW)

Correspondence Address: LAW OFFICES OF LAI AND ASSOCIATES, P.C., 5800 RANCHESTER STE 200, HOUSTON, TX, 77036, US

(21) Appl. No.: 11/307,839

(22) Filed: Feb. 24, 2006

(51) Int. Cl. H05K 7/20

(52) U.S. Cl. 165/80.4; 165/104.33; 361/699

(57) ABSTRACT

This invention discloses a chip heat dissipation system for chip heat dissipation and a manufacturing method and structure of heat dissipation device thereof. The chip heat dissipation system includes a heat dissipation device, a heat exchange device, a pump assembly device and at least two pipes. The heat dissipation device is used for receiving a waste heat from the chip, and the heat dissipation device is composed of a thermal conduction material, including a metal material and a bracket structure of carbon element; the heat exchange device is used for discharging the waste heat; the at least two pipes are used for connecting at least two joints of the heat dissipation device and the heat exchange device; and the pump assembly device is used for circulating a fluid between the heat dissipation device and the heat exchange device by the at least two pipes. The bracket structure of carbon element has high thermal conductivity, so as to improve the heat conduction efficiency. The manufacturing method for the thermal conduction material can be made with chemical vapor deposition, physical vapor deposition, melting or the other materials preparation method. The bracket structure of carbon element can be coated on a surface of the metal material and also can be mixed into the metal material.

### FIELD OF THE INVENTION

The present invention relates to a chip heat dissipation system and a structure of a heat dissipation device and a manufacturing method and, more particularly, to the heat dissipation device which is composed of a thermal conduction material having a metal material and a bracket structure of carbon element.

### BACKGROUND OF THE INVENTION

In recent years, the pace of high technology industry development is extremely fast, the development of electronic components is toward small volumes and high densities, especially for central processing units (CPU). The CPUs are a key point for IC research and development and are applied for personal computers (PC) and various servers. Therefore, the performance for PCs and various servers depends on the efficacy of CPUs. The CPU chips can increase working clocks to improve efficiency after advancing the fabrication. Relatively, much waste heat is then generated and is unavoidable. The performance of the CPU chips will be decreased and destroyed if the waste heat is unable to eliminate appropriately. Therefore, various heat conduction materials are provided to improve the efficiency of heat dissipation.

Referring to FIG. 1, a schematic diagram illustrates a conventional air blown chip heat dissipation system 1. The conventional air blown chip heat dissipation system 1 comprises a central processing unit (CPU) chip 11, a substrate 12 and a heat dissipation device 13. The CPU chip 11 further comprises a plurality of pins 111 for connecting to the substrate 12. The substrate 12 can be a conventional main board or a display card. The heat dissipation device 13 comprises a fan 131 and can be pasted on an upper surface of the chip 11 closely through a thermal greaser 32. The waste heat generated by the operation of the CPU chip 11 can be conducted by the thermal grease 132 to the heat dissipation device 13. The waste heat existed in the heat dissipation device 13 can be discharged to an outside via an air stream produced by the fan 131.

However, the efficiency of heat dissipation depends on the size and the rotational speed of the fan 131. The waste heat can not be discharged to the outside from the heat dissipation device 13 and the waste heat generated by the CPU chip 11 can not be conducted to the heat dissipation device 13. Furthermore, much waste heat is then accumulated by the CPU chip 11 and the efficiency of the chip is decreased.

Referring to FIG. 2, a schematic diagram illustrates a conventional water cooled chip heat dissipation system 2. The conventional water cooled chip heat dissipation system 2 comprises a central processing unit (CPU) chip 21, a substrate 22, a heat dissipation device 23, a heat exchange device 24 and a pump assembly device 25. The CPU chip 21 further comprises a plurality of pins 211 for connecting to the substrate 22. The substrate 22 can be a conventional main board or a display card. The heat dissipation device 23 can be pasted on an upper surface of the CPU chip 21 closely through a thermal grease 231. The pump assembly device 25, the heat dissipation device 23 and the heat exchange device 24 can be connected each other through pipes 251. Water (not shown in FIG. 2) taken by the pump assembly device 25 circularly flows between the heat dissipation device 23 and the heat exchange device 24 via the pipes 251.

The waste heat generated by the operation of the CPU chip 21 is conducted by the thermal grease 231 to the heat dissipation device 23. The waste heat existed in the heat dissipation device 23 is then conducted to the heat exchange device 24 through the circulation flow of the water. The heat exchange device 24 further comprises a fan 241. Lastly, the waste heat existed in the heat exchange device 24 is discharged to an outside via an air stream made by the fan 241.

The heat dissipation system of the above described is that the waste heat is conducted to the heat dissipation device 24 by using the circulation flow of water which has high specific heat. Therefore, the efficiency of heat dissipation can be improved when water is pressurized by the pump assembly device 24 in order to speed up the rate of circulation of water. There is no restriction for volumes because the heat exchange device 24 is not set on the substrate 22. In another word, the efficiency of heat dissipation can be improved by increasing the size and the rotational speed of the fan 241. Accordingly, the efficiency of heat dissipation for the CPU chip 21 can also be improved efficiently.

Referring to FIG. 3, a schematic diagram illustrates a structural decomposition of the heat dissipation device 23 according to FIG. 2. The heat dissipation device 23 can be decomposed into an upper-half part 232 and a lower-half part 233 symmetrically. The upper-half part 232 is the same as the lower-half part 233. The lower-half part 233 further comprises two semicircle holes 2331 and a fillister 2332 which is formed within the lower-half part 233. The upper-half part 232 also comprises two semicircle holes 2321 and a fillister (not shown in FIG. 5) which is formed within the upper-half part 232. When the upper-half part 232 is combined with the lower-half part 233, the semicircle holes 2321, 2331 can be combined together to be circle holes. The circle holes can provide the pipes 251 to connect the heat dissipation device 33 to form gates which provide the fluid for incoming and outgoing. The fillisters within the upper-half part 332 and the lower-half part 333 further provide a channel for the fluid to enable the fluid within the heat dissipation device 33 to receive the waste heat via the conduction. The waste heat existed in the heat dissipation device 33 is taken out through the flow of the fluid.

Although the rate of circulation of water can be speeded up when water is pressurized by the pump assembly device, the waste heat may not be taken by water immediately if the heat conduction of the heat dissipation device is not good enough. Currently, the thermal conduction materials applying for the heat dissipation device usually include copper, silver, aluminum or alloys. The aforesaid materials possess high thermal conductivity. The thermal conduction materials are unable to satisfy the demand for heat dissipating when a large number of waste heats generated by CPU chips are increased substantially; hence an alternative thermal conduction material is an important issue.

Besides, diamonds are well known and have characteristics with the highest hardness, the fastest heat conduction, and the widest refraction range. Diamonds, therefore, are always one of more important materials in engineering due to the excellent characteristics. The thermal conductivity of diamonds at the normal atmospheric temperature is five times more than copper. Moreover, the thermal expansion factor of diamonds at high temperature is very small that shows the excellent efficiency of heat dissipation. The feature may help people to differentiate the adulteration of diamonds. In the prior art, many technologies and manufacture methods have been developed to make diamonds. The direct decomposition for hydrocarbons is the most familiar method like Microwave Plasma Enhance Chemical Vapor Deposition (MPCVD) and Hot Filament CVD (HFCVD). By the aforesaid methods, polycrystalline diamond films can be deposited. The characteristic of the polycrystalline diamond films is same as the single crystal diamonds.

Accordingly, a thermal conduction material is developed and comprises a metal material and a bracket structure of carbon element (e.g. diamonds). The thermal conduction material can improve the thermal conductivity substantially to satisfy the current thermal conduction materials with low efficiency of heat dissipation.

### SUMMARY OF THE INVENTION

The object of the present invention is to provide a chip heat dissipation system and a structure of a heat dissipation device and a manufacturing method. The chip heat dissipation system comprises a chip, a heat dissipation device, a heat exchange device, a pump assembly device and a plurality of pipes. The heat dissipation device is composes of a thermal conduction material having a metal material and a bracket structure of carbon element. The metal material can be copper, aluminum, silver, alloys or a metal material with high thermal conductivity. The bracket structure of carbon element can be diamonds. Moreover, the bracket structure of carbon element can be coated on a surface of the metal material or can be mixed into the metal material. The thermal conduction material of the heat dissipation device can be made by chemical vapor deposition (CVD), physical vapor deposition (PVD), melting, metal injection molding or other manufacturing methods. Therefore, the efficiency of heat dissipation for the heat dissipation device can be improved substantially.

Briefly, the chip heat dissipation system and the structure of the heat dissipation device and the manufacturing method provided by the present invention can satisfy the demand of the efficiency of heat dissipation for current chips. Therefore, the quality of the operation for these chips can be increased and the competition capability of the integrated circuit industry can also be improved.

Other features and advantages of the present invention and variations thereof will become apparent from the following description, drawings, and claims.

### BRIEF DESCRIPTION OF THE DRAWINGS

FIG. 1 is a schematic diagram illustrating a conventional air blown chip heat dissipation system;

FIG. 2 is a schematic diagram illustrating a conventional water cooled chip heat dissipation system;

FIG. 3 is a schematic diagram illustrating a structural decomposition of a heat dissipation device;

FIG. 4 is a schematic diagram illustrating a chip heat dissipation system according to an embodiment of the present invention;

FIG. 5 is a schematic diagram illustrating a structural decomposition of a heat dissipation device according to an embodiment of the present invention;

FIG. 6 is a schematic diagram illustrating another structural decomposition of the heat dissipation device according to an embodiment of the present invention;

FIG. 7 is a schematic diagram illustrating a manufacturing method for manufacturing a heat dissipation device of a chip heat dissipation system according to an embodiment of the present invention;

FIG. 8 is a schematic diagram illustrating another manufacturing method for manufacturing the heat dissipation device of a chip heat dissipation system according to an embodiment of the present invention; and

FIG. 9 is a schematic diagram illustrating a further manufacturing method for manufacturing the heat dissipation device of a chip heat dissipation system according to an embodiment of the present invention.

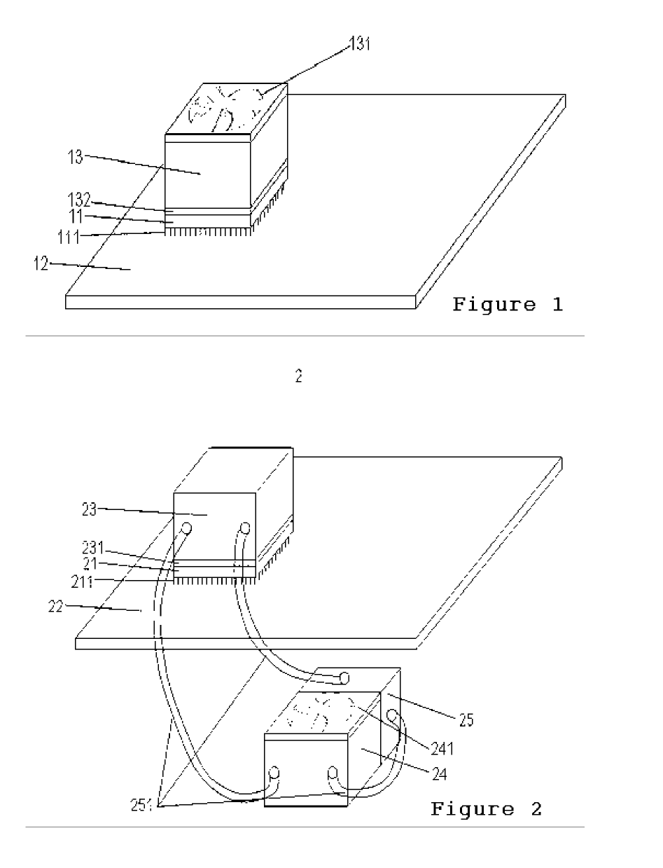

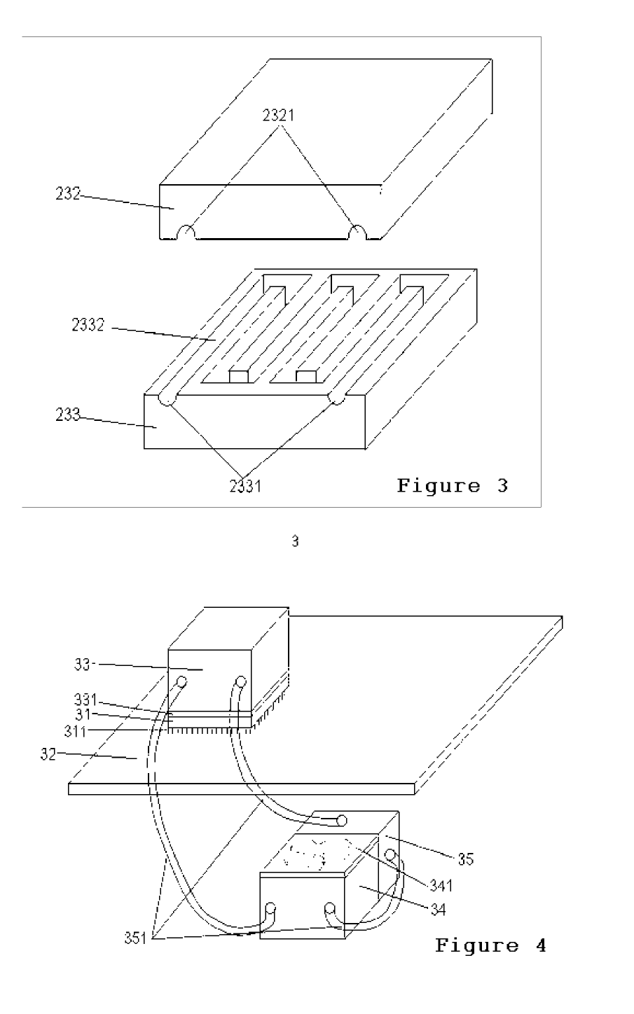

### DETAILED DESCRIPTION OF THE PREFERRED EMBODIMENTS

Referring to FIG. 4, a schematic diagram illustrates a chip heat dissipation system 3 according to an embodiment of the present invention. The chip heat dissipation system 3 comprises a chip 31, a substrate 32, a heat dissipation device 33, a heat exchange device 34 and a pump assembly device 35. The chip can be a central processing unit (CPU) chip and further comprises a plurality of pins 311 which is connected to the substrate 32. The substrate 34 can be a conventional main board or a display card. The heat dissipation device 33 can be pasted on an upper surface of the chip 31 closely through a thermal grease 331. The pump assembly device 35, the heat dissipation device 33 and the heat exchange device 34 can be connected each other via pipes 351. A fluid (not shown in FIG. 4) with high heat capacity coefficient which is taken by the pump assembly device 35 circularly flows between the heat dissipation device 33 and the heat exchange device 34 through the pipes 351. The heat dissipation device 33 is composed of a thermal conduction material. The thermal conduction material comprises a metal material and a bracket structure of carbon element. The metal material can be copper, aluminum, silver or alloys or other metal materials with high thermal conductivity. The bracket structure of carbon element is diamonds. The bracket structure of carbon element can be coated on a surface of the metal material or can be mixed into the metal material.

The waste heat generated by the operation of the chip 31 is conducted by the thermal grease 331 to the heat dissipation device 33. The waste heat is then conducted by the heat dissipation device 33 to the heat exchange device 34 via the circulation flow of a fluid (water) within the pipes 351. The heat exchange device 34 further comprises an air stream produce device 341. lastly, the waste heat is discharged by an air stream produced from the air stream produce device 341 to an outside.

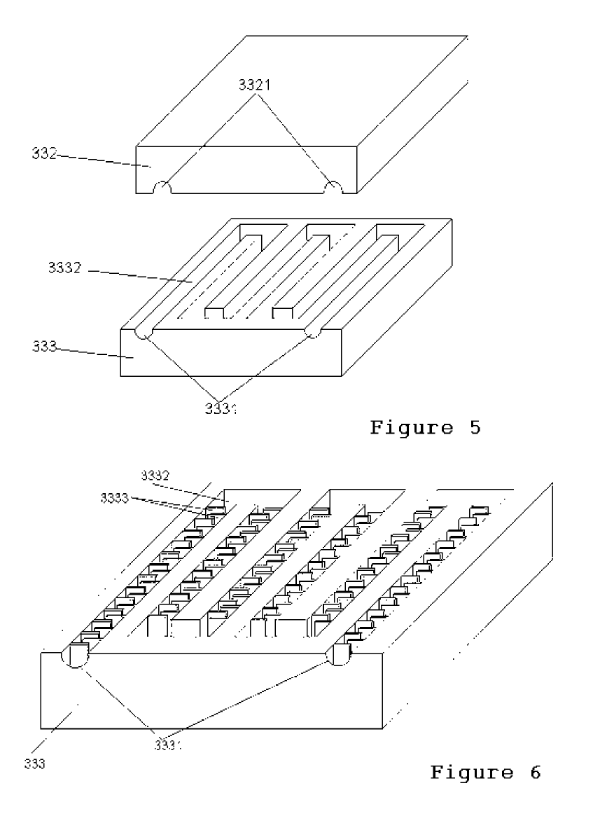

Referring to FIG. 5, a schematic diagram illustrates the structural decomposition of the heat dissipation device 33 according to FIG. 4. The heat dissipation device 33 can be decomposed into an upper-half part 332 and a lower-half part 333 symmetrically. The upper-half part 332 is the same as the lower-half part 333. The lower-half part 333 further comprises two semicircle holes 3331 and a fillister 3332 which is formed within the lower-half part 333. The upper-half part 332 also comprises two semicircle holes 3321 and a fillister (not shown in FIG. 5) which is formed within the upper-half part 332. When the upper-half part 332 is combined with the lower-half part 333, the semicircle holes 3321, 3331 can be combined together to be circle holes. The circle holes can provide the pipes 451 to connect the heat dissipation device 33 to form gates which provide the fluid for incoming and outgoing. The fillisters within the upper-half part 332 and the lower-half part 333 further provide a channel for the fluid to enable the fluid within the heat dissipation device 33 to receive the waste heat via the conduction. The waste heat existed in the heat dissipation device 33 is taken out through the flow of the fluid.

The heat dissipation device 33 is composed of the thermal conduction material according to the present invention. The waste heat existed in the heat dissipation device 33 can be conducted by the thermal conduction material with high thermal conductivity to the fluid speedily. The fluid pressurized by the pump assembly device 35 can circularly flow between the heat dissipation device 33 and the heat exchange device 34. Therefore, the waste heat existed in the heat dissipation device 33 can be conducted to the heat exchange device 34. Lastly, the waste heat existed in the heat exchange device 34 can be discharged by the air stream produce device 341 (a fan) of the heat exchange device 34 speedily to improve the efficiency of entire system. The efficiency of heat dissipation for the chip 31 can also be improved.

Referring to FIG. 6, a schematic diagram illustrates another structural decomposition of the lower-half part 333 of the heat dissipation device 33. The lower-half part 333 further comprises a plurality of heat sink fins 3333 which is set in the fillister 3332 and is connected the lower-half part 333 of the heat dissipation device 33. The waste heat is received via the conduction of the plurality of heat sink fins 3333 when the fluid flows around the channel formed from the fillister 3332. The plurality of heat sink fins 3333 can improve the efficiency of heat dissipation for the chip. The plurality of heat sink fins 3333 is also composed of the thermal conduction material according to the present invention. The thermal conduction material comprises a metal material and a bracket structure of carbon element to increase the thermal conductivity of the plurality of heat sink fins 3333. The efficiency of heat dissipation for entire system is also increased.

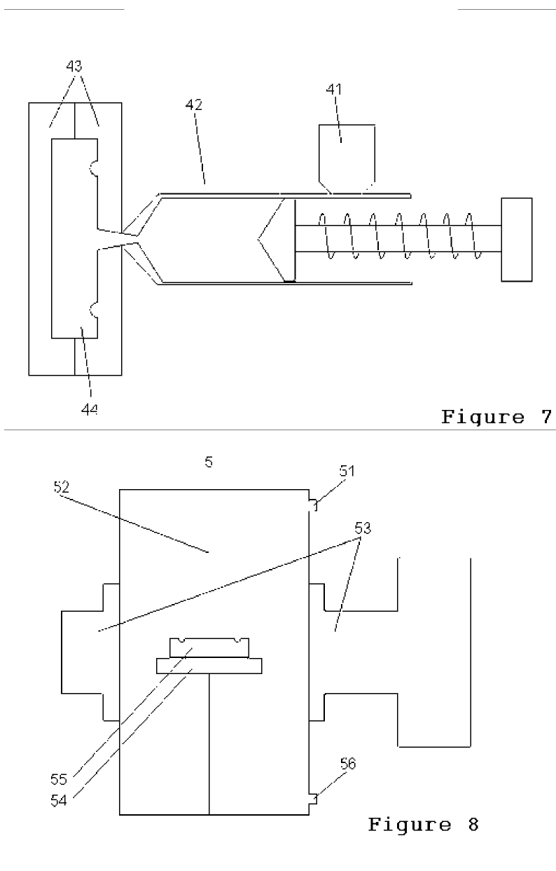

Referring to FIG. 7, a schematic diagram illustrates a manufacturing method for the heat dissipation device of the chip heat dissipation system according to an embodiment of the present invention. The manufacturing method uses a conventional metal injection molding 4. The conventional metal injection molding 4 comprises a mold material supplier 41, a mold material injector 42 and a mold 43. A mold material is injected by the mold material injector 42 to a cavity 44 of the mold 43 for molding. The mold material can be a metal material or a melt material which combines a metal with a bracket structure of carbon element. The metal material is copper, aluminum, silver or other metals with high thermal conductivity. The melting point of the bracket structure of carbon element is higher than any metal of the mentioned above. Therefore, the bracket structure of carbon element can be mixed with those metals to form a mold material. The structure of the metal injection molding is a form of the cavity 44. In the embodiment, the form of the cavity 44 can be the lower-half part 333 as shown in FIG. 5. Furthermore, the upper-half part 332 as shown in FIG. 5 can be obtained via the cavity 44. The lower-half part 333 is combined with the upper-half part 332 (using welding technique) to acquire the heat dissipation device 33 as shown in FIG. 4.

Referring to FIG. 8, a schematic diagram illustrates another manufacturing method of the heat dissipation device of a chip heat dissipation system according to an embodiment of the present invention. The manufacturing method comprises a conventional microwave plasma enhanced chemical vapor deposition 5 (MPCVD). The bracket structure of carbon element can be coated on a surface of a metal material through MPVCD, especially for the surface of the heat dissipation device 33 as shown in FIG. 4. The reaction procedure is that a mixed gas for desired reaction is delivered to a gas reaction room 52 from a gas entrance 51. At the same time, a microwave is generated by a microwave generation system 53 to activate the mixed gas in order to provide reactive ions for reacting. A surface of a metal material 55 on a carrier 54 is absorbed to form a bracket structure of carbon element film (diamond films). The metal material 55 is the heat dissipation device 33 formed by the manufacturing method as shown in FIG. 7. The heat dissipation device 33 can be composed of copper, aluminum, silver or other metal materials with high heat conductivity or alloys. Remaining gas is discharged via a waste gas exit 56. By the way mentioned above, a thermal conduction material coating diamond particles can be acquired. In the embodiment, the metal material 55 is the upper-half part 332 or the lower-half 333 as shown in FIG. 5. Therefore, the heat dissipation device 33 as shown in FIG. 4 can be formed after the bracket structure of carbon element film is deposited.

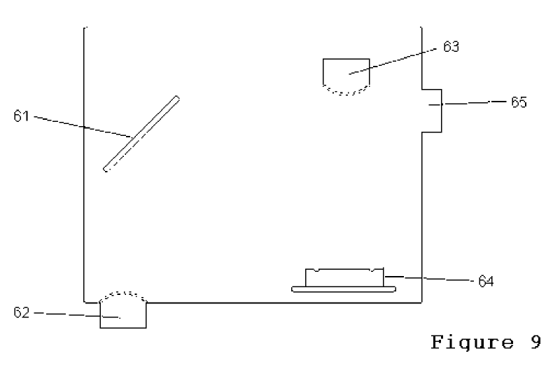

Referring to FIG. 9, a schematic diagram illustrates a further manufacturing method of the heat dissipation device of a chip heat dissipation system according to an embodiment of the present invention. The manufacturing method comprises a conventional ion beam sputtering 6. The ion beam sputtering 6 is a physical vapor deposition (PVD) for coating the bracket structure of carbon element on a surface of a metal material, especially for the surface of the heat dissipation device 33 as shown in FIG. 4. The manufacturing procedure is that a target 61 is molded by the bracket structure of carbon element. The placement angle of the target 61 and the shooting direction of ion beam of a first ion gun 62 are approximately forty five degrees. The bracket structure of carbon element particles fired by the first ion gun 62 can fly to the front of a second ion gun 63. The bracket structure of carbon element particles are then sputtered to the surface of a metal material 64 to form uniform the bracket structure of carbon element films by providing enough kinetic energy from the first ion gun 62. The metal material 64 is the heat dissipation device 33 formed by the manufacturing method as shown in FIG. 7. The heat dissipation device can be copper, aluminum, silver or alloys or other metal materials with high thermal conductivity. The remaining bracket structure of carbon element particles are discharged by a waste gas exit 65. In the embodiment, the metal material 64 is the upper-half part 332 or the lower-half 333 as shown in FIG. 5. Therefore, the heat dissipation device 33 as shown in FIG. 4 can be formed after the bracket structure of carbon element film is deposited

By the way mentioned above, a chip heat dissipation system and a structure of a heat dissipation device and a manufacturing method can increase the efficiency of heat dissipation substantially to satisfy the demand for discharging the waste heat generated by integrated circuit chips.

Although the features and advantages of the embodiments according to the preferred invention are disclosed, it is not limited to the embodiments described above, but encompasses any and all modifications and changes within the spirit and scope of the following claims.

What is claimed is:

1. A chip heat dissipation system, applied to a chip for heat dissipation, comprising:
a heat dissipation device for receiving a waste heat from said chip, said heat dissipation device being composed of a thermal conduction material, said thermal conduction material comprising a metal material and a bracket structure of carbon element;
a heat exchange device for discharging said waste heat;
at least two pipes for connecting at least two joints of said heat dissipation device and said heat exchange device; and
a pump assembly device for pressurizing a fluid to circularly flow between said heat dissipation device and said heat exchange device by way of said at least two pipes.

2. The chip heat dissipation system of claim 1, wherein said chip is a central processing unit (CPU) chip.

3. The chip heat dissipation system of claim 1, wherein said metal material is copper.

4. The chip heat dissipation system of claim 1, wherein said metal material is silver.

5. The chip heat dissipation system of claim 1, wherein said metal material is aluminum.

6. The chip heat dissipation system of claim 1, wherein said metal material is a metal alloy with high thermal conductivity.

7. The chip heat dissipation system of claim 1, wherein said bracket structure of carbon element is diamonds.

8. The chip heat dissipation system of claim 1, wherein said thermal conduction material is made by chemical vapor deposition (CVD).

9. The chip heat dissipation system of claim 1, wherein said thermal conduction material is made by physical vapor deposition (PVD).

10. The chip heat dissipation system of claim 1, wherein said thermal conduction material is made by melting.

11. The chip heat dissipation system of claim 1, wherein said heat dissipation device is made by metal injection molding.

12. The chip heat dissipation system of claim 1, wherein said heat dissipation device further comprises a plurality of heat sink fins.

13. The chip heat dissipation system of claim 12, wherein said plurality of heat sink fins is composed of said thermal conduction material.

14. The chip heat dissipation system of claim 1, wherein said heat exchange device further comprises an air stream produce device.

15. The chip heat dissipation system of claim 14, wherein said air stream produce device is a fan.

16. The chip heat dissipation system of claim 1, wherein said fluid is water.

17. A method for manufacturing a heat dissipation device, comprising:
employing a manufacturing to produce a thermal conduction material having a metal material and a bracket structure of carbon element; and
employing a die to enable said thermal conduction material to form a heat dissipation device and said heat dissipation device having a shell structure, at least two holes being formed on said shell structure, and at least a channel being formed within said shell structure to connect said at least two holes.

18. The method for manufacturing a heat dissipation device of claim 17, further comprising providing copper to be said metal material.

19. The method for manufacturing a heat dissipation device of claim 17, further comprising providing silver to be said metal material.

20. The method for manufacturing a heat dissipation device of claim 17, further comprising providing a metal alloy having a thermal conduction material to be said metal material.

21. The method for manufacturing a heat dissipation device of claim 17, further comprising providing diamonds to be said bracket structure of carbon element.

22. The method for manufacturing a heat dissipation device of claim 17, further comprising employing CVD to form said thermal conduction material.

23. The method for manufacturing a heat dissipation device of claim 17, further comprising employing melting to form said thermal conduction material.

24. The method for manufacturing a heat dissipation device of claim 17, further comprising employing metal injection molding to be said die.
